(19) United States
(12) Patent Application Publication
(10) Pub. No.: US 2018/0114691 A1
(43) Pub. Date: Apr. 26, 2018

(54) METHODS FOR ETCHING AS-CUT SILICON WAFERS AND PRODUCING SOLAR CELLS

(71) Applicant: SolarWorld Americas, Inc., Hillsboro, OR (US)

(72) Inventor: Konstantin Holdermann, Hillsboro, OR (US)

(21) Appl. No.: 15/842,933

(22) Filed: Dec. 15, 2017

Related U.S. Application Data
(63) Continuation-in-part of application No. 13/960,876, filed on Aug. 7, 2013, now abandoned.

(51) Int. Cl. H01L 21/02; H01L 31/18

(52) U.S. Cl. CPC H01L 21/02019; H01L 31/1868; H01L 31/1804

(57) ABSTRACT

A method for producing a silicon solar cell, including inline etching of a saw damaged as-cut Si wafer, the inline etching including etching a first surface of the as-cut Si wafer with an etchant solution, wherein a first amount is etched from the first surface and the first surface is polish etched; and etching a second surface of the as-cut Si wafer with the etchant solution, wherein a second amount is etched from the second surface, wherein the first amount is greater than the second amount, wherein the saw damaged as-cut Si wafer is not subjected to an etching prior to said inline etching.

### CROSS-RELATED APPLICATIONS

This application is a continuation in part of U.S. application Ser. No. 13/960,876 filed on Aug. 7, 2013, which is hereby incorporated by reference in its entirety.

### TECHNICAL FIELD

Various aspects relate generally to methods for etching silicon wafers and solar cell production.

### BACKGROUND

Silicon (Si) wafers cut using methods such as diamond wire cutting or slurry cutting are contaminated with metallic and/or organic contaminants, although nowadays, the slurry cutting process, which usually produces a higher metal contamination than the diamond wire cutting process, has mostly been replaced by the diamond wire cutting process. After the cutting, the saw damaged, as-cut Si wafers typically undergo a pre-cleaning to remove the attached strips of epoxy glue used during the cutting. The epoxy is used as a strong gluing substrate to glue the heavy Si crystal (i.e. Si ingot) to a plate in order to have it strongly fixed during the sawing process. Therefore, after the cutting, the Si wafers are still glued at one edge to the remaining epoxy strip. Dependent on the epoxy type, this pre-cleaning process may include hot water in combination with surfactant or without surfactant, often with ultrasonic support. Also, organic acids may be used, e.g. diluted acetic acid, lactic acid, or oxalate acid.

However, this pre-cleaning does not sufficiently remove all of the metallic and/or organic contaminants on the as-cut Si wafers. Depending on the cutting and the pre-cleaning methods, the surfaces of the as-cut Si wafer remain contaminated with silicon carbide, organic residues like solvents, surfactants, glue stains, etc., and/or residue left over from fingerprints during the handling of the as-cut Si wafers. Thus, after pre-cleaning, the as-cut Si wafers are still saw damaged and have metallic and/or organic contaminants on their surfaces.

Conventional Si solar cell production methods perform a second cleaning process on these contaminated, as-cut Si wafers to remove the contaminants prior to etching the wafers. It is known that the homogeneity of either an alkaline polish etched surface or an alkaline texture etched surface depends strongly from the quality of an organic free wafer surface. The industrial production of high efficiency cells uses ozone or hydrogen-peroxide in acidic or alkaline solution, often in combination with an additional surfactant, in this second cleaning step (final clean) prior to performing the alkaline polish etch process and/or the alkaline texture etch process. Both alkaline etching processes, if executed in a batch process, typically involve etching an equal amount of material off each side of the as-cut Si wafer, (i.e. symmetrical etching). Known methods include alkaline etching of as-cut Si wafers in an inline tool where the wafer top side is texture etched while the wafer bottom side is etched at the same time, but with a rough surface on the bottom side, which later requires an additional polish etching step removing several additional μm off of the wafer bottom side. A single side etching of the as-cut Si wafer would immediately bow the wafer, thereby leading to a lower performance solar cell or the inability to produce a solar cell from the bowed Si wafer altogether.

### SUMMARY OF THE INVENTION

A method for inline asymmetrically etching as-cut silicon wafers, the method including etching a first surface of the as-cut Si wafer with an etchant solution, wherein a first amount is etched from the first surface; and etching a second surface of the as-cut Si wafer with the etchant solution, wherein a second amount is etched from the second surface, wherein the first amount is greater than the second amount, and wherein the as-cut Si wafer is saw-damaged and is not subjected to another etching prior to the etching of the first surface and the etching of the second surface. This asymmetrical etching may include polish etching the first surface (i.e. the bottom side).

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a first exemplary etching process according to some aspects;

FIG. 2 shows a second exemplary etching process according to some aspects;

FIG. 3 shows a flowchart describing methods for producing a solar cell according to some aspects;

FIG. 4 shows SEM images of an acidic etched as-cut Silicon wafer according to some aspects; and

FIG. 5 shows SEM images of an alkaline etched as-cut Silicon wafer according to some aspects.

FIG. 6 shows a flowchart describing methods for asymmetrically etching as-cut Si wafers.

### DESCRIPTION

The following detailed description refers to the accompanying drawings that show, by way of illustration, specific details and embodiments in which the invention may be practiced.

The word “exemplary” is used herein to mean “serving as an example, instance, or illustration.” Any embodiment or design described herein as “exemplary” is not necessarily to be construed as preferred or advantageous over other embodiments or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one. The terms “proper subset”, “reduced subset”, and “lesser subset” refer to a subset of a set that is not equal to the set, i.e. a subset of a set that contains less elements than the set.

The term “acidic etchant agent” as used herein refers to chemical compositions, such as aqueous solutions of an acidic agent with a H₃O⁺ concentration higher than 1 mol/L, and may contain at least nitric acid as oxidizing agent and additional fluoride to dissolve the oxidized silicon.

The term “alkaline etchant agent” as used herein refers to chemical compositions, such as aqueous solutions of an alkaline agent with a OH⁻ concentration higher than 1 mol/L, and may contain an alkaline solution as an oxidizing agent and to dissolve the oxidized silicon.

The term “saw-damaged” as used herein refers to a Si wafer which is surface damaged by the sawing and/or contaminated by, for example, metals or organic residues originating from the saw process.

The term “pre-cleaned” as used herein refers to a saw-damaged wafer as-cut, which has been pre-cleaned with hot water in combination with surfactant that can be supported by ultrasound; or with hot water without surfactant, that can be supported by ultrasound; or with an organic acid, such as diluted acetic acid, lactic acid or oxalic acid in order to release the epoxy glue, and possibly reduce the amount of metallic contaminants on the surfaces of the wafer. However, this pre-cleaning removes a negligible, if any, amount of Si material from the as-cut Si wafer surface, and is therefore not considered to be etching within this disclosure.

The term “aqueous solution” as used herein refers to a water based solution.

Various aspects are based on the inventor's finding that high efficiency passivated emitter rear cell/contact (PERC) solar cells are achievable by an asymmetrical, in-line etching process of as-cut Si wafers implemented at the beginning of the solar cell production process as described herein. Namely, the etching process includes etching a first amount off of a first side of an as-cut Si wafer while etching a second amount, which is greater than the first amount, off of a second side of the as-cut Si wafer, wherein the second side is later to be the rear-side of the solar cell. The first amount may be in the range of about 0.5 μm to about 3 μm, while the second amount may be in the range of about 7 μm to about 11 μm. These amounts are determined as the depth from each surface of the as-cut Si wafer.

The asymmetrical, inline etching process of this disclosure is performed at the initial stages of solar cell production after the Si wafers (mono or quasi-mono Si wafers) are cut and pre-cleaned to remove epoxy used during the cutting process. This asymmetrical, inline etching process subjects the upper surface of the as-cut Si wafer to a slight etching, e.g. removing about 0.5 to about 3.0 μm of Si material, while the lower surface is etched up to about 11 μm, for example, up to about 9 μm. The etchant “rain box” is installed at the beginning or close to the beginning of the etching process, and the etching of both wafer sides begins simultaneously or nearly simultaneously. The etching of the entire upper surface may be performed during a fraction of the etching time of the lower surface. This etching of the upper surface is sufficient to avoid bowing of the etched wafer and significantly improves the mechanical strength of the wafer by removing small cracks and fissures resulting from the cutting process and also removing any remaining contaminants from the wafer's surfaces. The etchant solution may be either acidic or alkaline.

In some aspects, the use of an acidic agent in the etchant solution for the asymmetrical, in-line etching process provides a further advantage of not requiring an additional cleaning step after the initial pre-clean (removal of epoxy glue) which may be needed when an alkaline etchant solution is used, i.e. the cleaning requirements of the as-cut Si wafer are reduced. The homogeneity of an alkaline damage etched surface or alkaline texture etched surface depends strongly on the quality of an organic contaminant free wafer surface. And because the saw damaged, as-cut Si wafers still contain trapped metallic and/or organic contaminants from the cutting and/or pre-cleaning process, the Si wafers may need to undergo an additional step of an ozone or hydrogen-peroxide cleaning (may also include a surfactant) prior to any further alkaline etching. However, if the acidic etchant agent is selected for the etchant solution in the in-line etching process of the as-cut Si wafer, no pre-cleaning of the wafer is required due to the strong oxidizing nature of the nitric acid that is used as a key component in the etching process. Accordingly, by using an acidic etchant agent, this additional cleaning step may be completely bypassed, thereby reducing the footprint of the solar cell manufacturing process and increasing solar cell production speed.

In selecting an acidic etchant agent for the etchant solution in order to asymmetrically etch the as-cut Si wafers, the metallic and organic contaminants may be effectively removed while at the same time controlling the surface roughness of the Si wafers. By removing these contaminants, cell degradation is minimized and allows for fine tuning of the amount of roughness of the Si surface for the ensuing application of the passivation layer.

In some aspects, the asymmetrical, in-line acidic etching process may save up to about 45% on hydrofluoric acid and nitric acid, greatly reduced the amount of by-product NOₓ, and lower the cost of chemical treatment during the manufacturing process compared to conventional etching processes. Furthermore, the processes described in this disclosure may be implemented with the use of lower grade chemicals (e.g. technical/industrial grade hydrofluoric and/or nitric acid) resulting in additional reduced costs without compromising the high efficiency of the resulting solar cells.

Another advantage of the etching process in some aspects of this disclosure is that the overall solar cell production process is streamlined and provides for a lower amount of etching throughout the whole process. This results in a higher yield of the production of solar cells with increased mechanical integrity (i.e. thicker solar cells as a result of lower amounts of etching from their surface) or an increased yield of solar cells since the initial Si wafers may be sliced thinner because of the reduced amounts of total etching required by the processes described herein. In total, the asymmetrical etching processes of the as-cut Si wafers described in some aspects of this disclosure etch up to about 10 μm less material off of the Si wafers as compared to conventional batch etching processes or to the alkaline inline texture etching process which requires an additional acidic single side polish etching process.

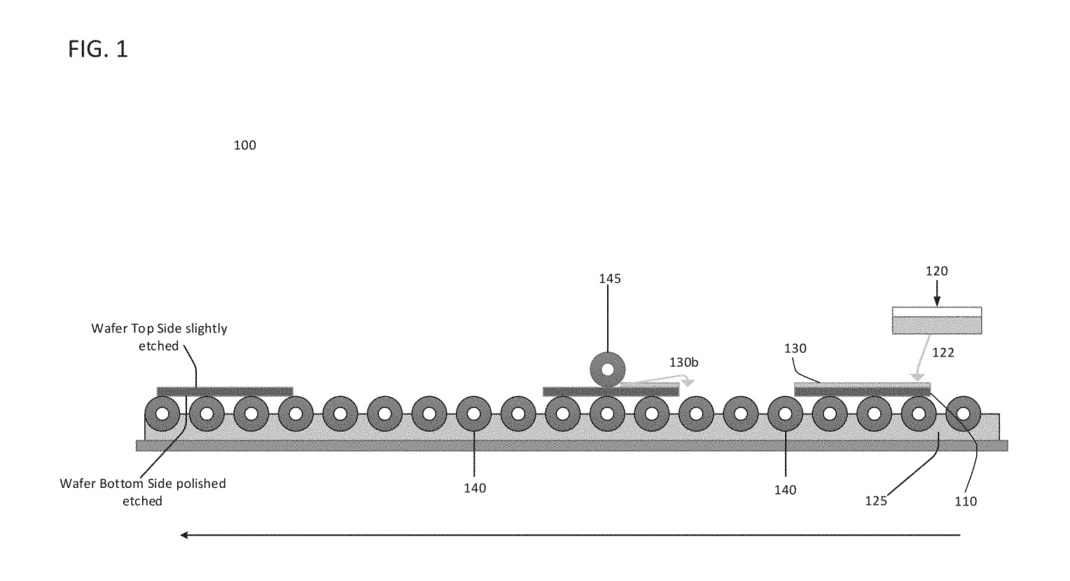

FIG. 1 shows a first, in-line etching process 100 of an as-cut Si wafer 110 in some aspects. It is appreciated that etching process 100 is exemplary in nature and may therefore be simplified for purposes of this explanation. In case of the usage of grooved transport rollers, the rollers are partially submerged in the etchant solution 125 as shown in FIG. 1. In case of the usage of porous rollers, the etchant is fed by a tank to the inside of the rollers, e.g. through the rotating axes, and applied to the wafer surface via pores leading from the axes to the outer surface of the rollers, i.e. the rollers are not submerged in any etchant. In some aspects, the use of the porous rollers may be selected in order to reduce evaporation of the etchant solution.

The saw damaged, as-cut Si wafer 110 is subjected to in-line etching process shown in 100 after the cutting of the wafer and prior to any other etching processes. The Si wafer 110 may be subjected to a pre-cleaning prior to the in-line etching process 100 in order to remove epoxy residues from cutting, e.g. diamond wire cutting.

The wafer 110 is placed on a plurality of transport rollers 140 at least partially submerged in an etchant solution 125 (note: only one transport roller is indicated by reference number 140 both before and after top side roller 145, but it is appreciated that 140 references all bottom side rollers). The transport rollers 140 may be grooved or porous, so that as the wafer 110 moves down the line (i.e. towards the left in FIG. 1), the transport rollers 140 provide the bottom side of the wafer 110 with etchant solution 125. The porous transport rollers provide the etchant solution through small holes to the outer surface from their inside (e.g. from the axis), and not from being partially submerged in an etchant solution, and apply the etchant solution to the wafer surface as the wafer moves along the rollers. The slight etching of the wafer 110 top side is performed with the use of an etchant “rain box” 120, an etchant filled container located above the transport roller with slots or perforations configured to rain, drip, or spray 122 etchant solution on the top side of the wafer 110 so that the etchant solution accumulates 130 on the whole wafer top side. In this manner, both the bottom side (i.e. first surface) and the top side (i.e. second surface) of the wafer 110 are etched. While only one rain box 120 is shown in FIG. 1, it is appreciated that a plurality of rain boxes may be implemented in order to better control the amount of etchant solution introduced to the wafer 110 top side.

As the wafer moves along the inline etching process 100, the etchant solution accumulated on the top side of the wafer is removed 130b. In FIG. 1, this is done with the use of a single top side roller 145, but it is appreciated that other devices may be used, e.g. another roller, squeegee(s), sweeper(s), air blower(s) (e.g. one or more air knives), etc., either alone or in combination with one another. The top side roller 145 may remove the majority of the etchant on the top side (i.e. by squeezing the etchant solution from the top of the wafer surface), but may leave small amounts of etchant behind. However, the efficacy of the etchant solution left on the top side is quickly consumed, so that the top side undergoes minimal etching after the removal of the etchant solution by the top side roller 145. However, the bottom side of the wafer 100 continues to be etched as it is transported along the transport rollers 140 after the removal of the etchant solution from the top side 130b until the end of the process shown in 100. The amount etched off of the top side of the wafer 110 may be controlled by a number of different variables, including the distance between the rain box 120 and the top side roller 145, the speed at which the wafer 110 travels along the transport rollers, and the temperature of etchant (which may be adjusted with the use of a heater). For example, the wafer transport speed may be in the range of about 0.5 to about 2.5 m/min, e.g. 0.8 m/min, 1.80 m/min, or 2.20 m/min; the distance from the top side roller 145 to the rain box 120 may be in the range of about 50 to about 500 mm, e.g. about 80 mm, about 130 mm, or about 300 mm. In some aspects, the top side of the wafer 110 is slightly etched in an amount ranging from about 0.5 μm to about 3 μm while the bottom side is polish etched about 7 μm to about 11 μm. In some aspects, due to the residual etchant solution left in puddles on the top side after removal (e.g. by top side roller 145), the top side may not be polish etched, but may in fact have irregular surface compared to the polish etched bottom side.

In some aspects, any remaining etchant solution is removed from the wafer 110 bottom side at the completion of the process shown in 100. This may be done with at least one air blower (e.g. air knife), squeegee, or the like, or also may be done by applying a cleaning/rinsing solution. In some aspects, after the acidic or alkaline etching process shown in FIG. 1, the wafers are subjected to a water rinse which rinses the wafer top side and bottom side. This may be followed by a short alkaline bath (in the case of acidic etching) to remove porous silicon nanolayers that are formed on both wafer surfaces when leaving the acidic etching module. This short alkaline bath may be followed by a subsequent acidic cleaning using HCl or HF, either alone or in combination. In some aspects, in the case of alkaline etching, the water rinse is followed by acidic cleaning and neutralization using HCl or HF acid (alone or in combination).

Additionally, depending on the type of etchant agent used in the etchant solution 125, i.e. acidic or alkaline etchant agent, the etchant solution 125 located beneath the rollers 140 and/or in the etchant rain box 120 may be heated, e.g. with a flow heater. In the case where an acidic etchant agent is used, the heater may be configured to heat the etchant solution in the range of about 25° C. to about 50° C., preferably between 30° C. to 50° C., and more preferably between 35° C. to 50° C. In the case of where an alkaline etchant agent is used in the etchant solution, the heater may be configured to heat the etchant solution from about 55° C. to about 95° C.

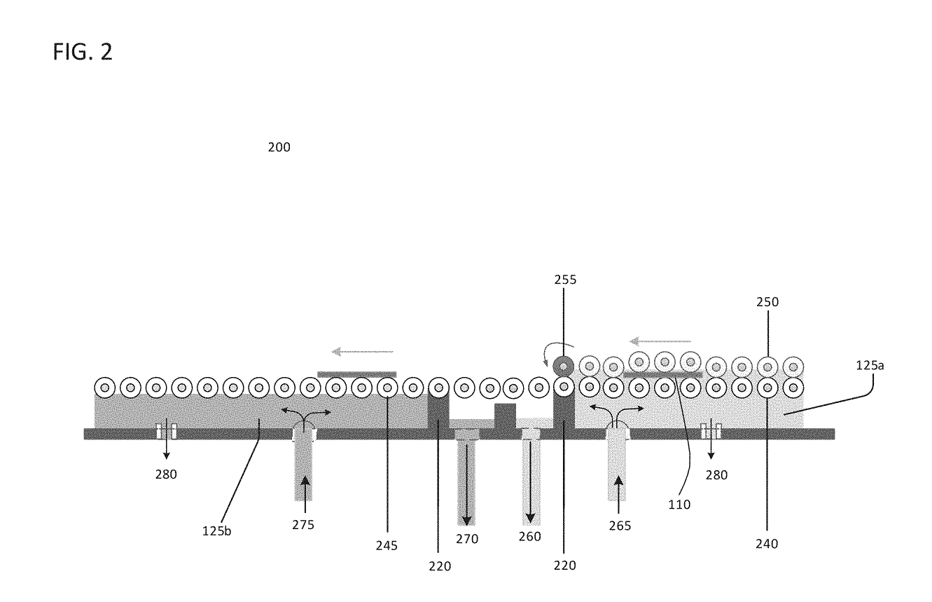

FIG. 2 shows a second, in-line etching process 200 of an as-cut Si wafer 110 in some aspects. It is appreciated that etching process 200 is exemplary in nature and may therefore be simplified for purposes of this explanation.

Similarly as described in FIG. 1, the saw damaged, as-cut Si wafer 110 is subjected to etching process 200 after the cutting of the wafer and prior to any other etching processes. The wafer 110 may undergo a pre-cleaning prior to the in-line etching process 200 in order to remove epoxy residues remaining from the cutting of the Si wafers, e.g. by diamond wire cutting.

For in-line etching process 200, an additional array of rollers 250 may be used to keep the wafers submerged and to etch the wafer 110 top side. In one aspect, as shown in FIG. 2, the top rollers 250 are partially submerged and the bottom rollers 240 are fully submerged in the etchant solution 125a in order to etch both the top and bottom sides of the wafer 110. (Note: only one top side roller is indicated by reference number 250 and one bottom side roller is indicated by 240, but it is appreciated that 250 refers to all of the top side rollers and 240 refers to all of the bottom side rollers to the right of top side removal roller 255). Here, the bottom rollers may be grooved, but it is not required. In another aspect, the right side of the process (with respect to top side removal roller 255) does not use top rollers 250, but instead implements 1 or more rain boxes and grooved or porous bottom rollers 240 (similar to what is shown in FIG.1). If the rollers are porous, then the etchant solution is fed through the axes of the rollers and to the wafer surface through pores extending from the axis to the outer roller surface as previously described.

As the wafer 110 moves along the process (to the left), both the top side and bottom side of the wafer are etched. The top side rollers 250 and the top side etchant solution removal roller 255 may be configured to move perpendicularly to the wafer's movement as the wafer passes beneath them. This is shown by the three top side rollers 250 located above the wafer 110 which are at a different level than the other top side rollers in FIG. 2.

As the wafer 110 moves along the in-line process 200, the etchant solution is (largely) removed from the top side of the wafer 110 by removal roller 255 located above the bottom side rollers and the first (i.e. right) barrier 220. Etchant solution leaking from bath 125a between the top side removal roller 255 and its corresponding bottom roller 240 above the first barrier 220 is drained 260 and may be fed back through 265 similar to the etchant solution that is drained through adjustable hole 280 and fed back into the first etchant solution 125a bath tank via 265 (or 275 in the second etchant solution 125b bath) in order to maintain a balanced (i.e. constant) etchant solution bath level. As described with respect to FIG. 1, squeegees, air blowers, air knives, or the like, may also be used to remove the etchant solution from the top side of the wafer 110. Also, a small remainder of etchant solution may remain on the top side after removal by 255 and this remaining etchant solution may continue to slightly etch the top side until the solution has completely reacted. In some aspects, the space between the barriers 220 may be used to rinse or spray the entire wafer top side with water or any other protective liquid, e.g. polyethylene glycol (PEG), with a separate rain box, nozzles or the like (not pictured), to immediately remove this remaining etchant solution and to provide a homogeneously etched wafer top side. The overflowing or dripping of this liquid (e.g. water, PEG, etc.) may be caught by a collection pan (not pictured) installed between both barriers 220, below the wafers that drains the collected solution via a separate waste-line. The remaining water/PEG layer at the top side of the wafer would not disturb the etching of the wafer bottom side in between and to the left of the barrier(s) 220, as it sticks to the wafer upside.

The etch removal of the top side (and of the bottom side) of the wafer is determined e.g. by the length of this etchant solution bath, the transport speed of the wafers, and/or the process heat of the etchant solution bath.

In the portion of the process to the left of removal roller 255, the bottom side rollers 245 may have either grooves or pores. In the case that grooved rollers are used, the rollers are partially submerged in the etchant solution bath 125b, as shown in FIG. 2. If porous rollers are used, the etchant solution comes from a supply tank located underneath and connected to the axes of the rollers, and through the pores to the wafer surface. The liquid pushes from the axes of the rollers to the outside of the rollers through the pores, and reaches the bottom side of the wafer as the rollers turn. The etchant solution may then drop, and flow back to the underneath tank.

After the removal of the etchant solution from the top side by removal roller 255 (and, optionally, by a water/PEG rinse as previously described), the wafer 110 continues to be etched on the bottom side by rollers 245. Accordingly, the bottom side of the wafer may be polish etched, while the top side of the wafer is not etched furthermore.

The location of the barrier 220 with the top side removal roller 255 may be chosen to effectively manage the amount of time the wafer 110 remains submerged between top side rollers 250 and bottom side rollers 240 in order to etch a desired amount from the top side surface.

In some aspects, any remaining etchant solution is removed from the wafer 110 bottom side at the completion of the process shown in 200. This may be done first with at least one air blower (e.g. air knife), squeegee, or the like, or followed by a water rinse that may be applied to both wafer surfaces. In some aspects, therefore, a water rinse station may be located directly after the asymmetrical etching process. If acidic etching is used in process 200, the etched wafer may further be dipped in an alkaline bath after the water rinse (as described in FIG. 1).

Additionally, depending on the type of etchant agent used in the etchant solution 125a and/or 125b, e.g. acidic or alkaline etchant agent, the etchant solution 125a and/or 125b may be heated, e.g. with a flow heater. In the case where an acidic etchant agent is used in the etchant solution for 125a and 125b, the heater may be configured to heat the solution in either or both stages in the range of about 25° C. to about 50° C., e.g. between 30° C. to 50° C., e.g. preferably between 35° C. to 50° C. In the case of where an alkaline etchant agent is used in the etchant solution for 125a and 125b, the heater may be configured to heat the etchant solution either or both stages from about 55° C. up to about 95° C.

An advantage of the process shown in FIG. 2 is that the etching to the right and left of the barrier(s) 220 may be conducted at different temperatures, with different etchant solution compositions, and/or with different etchant solution concentrations. For example, the etchant solution 125a in the bath to the right of the barrier(s) 220 may be cooled down (with respect to the etchant solution 125b) to allow a very accurate and homogeneous etching removal of the upper side of the wafer. The bottom side of the wafer may then be etched further to the left of the barrier(s) 220, in the same inline process, with etchant solution 125b at a higher temperature without affecting the etched upper surface.

In some aspects, therefore, a single tank of etchant solution may exchange etchant solution between both etching baths, i.e. 125a and 125b are the same etchant solution with the same composition and the same temperature. In other aspects, two different etchant solutions may be used, respectively, in 125a and 125b, each with their respective tanks, wherein each etchant solution may have a different etchant composition, etchant component concentration, and/or temperature. In this aspect, each etchant solution will have its own bath-tank supplying and/or receiving drained etchant solution (e.g. shown in FIG. 2 with the two etchant solution baths, 125a and 125b, being different shades).

In some aspects, the use of porous rollers to the left of removal roller 255 may be used, i.e. for bottom side rollers 245. In this case, the second etchant solution is provided through the porous rollers 245 as previously described and not via being submerged in an etchant bath.

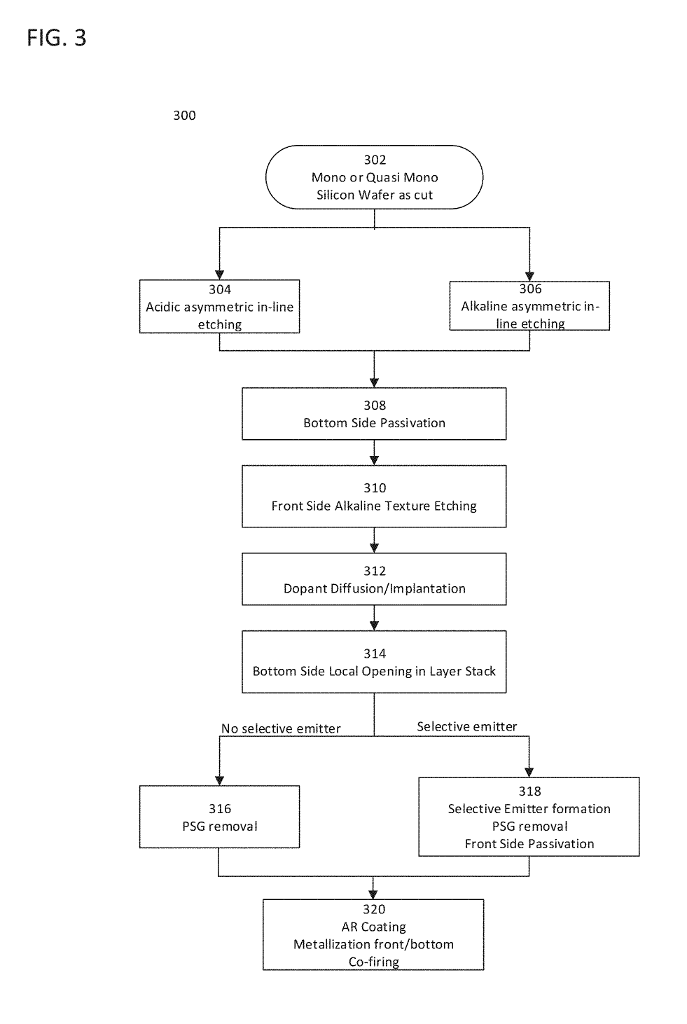

FIG. 3 shows a flowchart 300 describing the process for manufacturing a PERC (passivated emitter and rear contact) solar cell in some aspects. It is appreciated that flowchart 300 is exemplary in nature and may thus be simplified for purposes of this explanation.

In 302, the mono or quasi mono silicon, which may be produced by conventional silicon production methods, e.g. the Czochralski process, is cut, e.g. by diamond wire cutting, in order to obtain Si wafers. The Si wafers may be subjected to a pre-cleaning step in order to remove epoxy glues from the cutting process, but this pre-cleaning does not serve to etch the Si wafer surfaces.

After the Si wafers are cut (and pre-cleaned), they are subjected to an acidic asymmetrical in-line etching 304 or an alkaline asymmetrical in-line etching 306 as described herein, e.g. in FIGS. 1 and 2. In this step, a first surface (top side) of the as-cut Si wafer may slightly etched, e.g. between about 0.5 μm to about 3 μm, while a second surface (bottom side) is polish etched, e.g. between about 7 μm to about 11 μm. This etching method prevents the problem of bowing of the as-cut Si wafer as would be experienced by conventional single side etching, while also strengthening the mechanical integrity of the Si wafers by removing the cracks and fissures from the cutting process.

In the case where an acidic etchant agent is selected for the etchant solution 304, no additional cleaning of the as-cut Si wafer (e.g. by diamond wire cutting) is required due to the strong oxidizing nature of the acid, e.g. nitric acid, used. For a slurry cut wafer, usage of a filter may be needed to avoid enrichment of the etchant solution bath by dispersed particles of silicon carbide. The pre-cleaned, as-cut Si wafer may still contain surfactant and/or organic acids leftover from the cleaning process, in addition to other organic residues (e.g. fingerprints), but these contaminants do not need to be removed prior to the in-line acidic etching described herein.

In the case where the alkaline etchant is selected for the etchant solution 306, the as-cut Si wafer may be subjected to an additional clean (after the pre-clean) wherein organic and/or metallic contaminants are removed from the Si wafer surface. Typically, this includes the use of ozone or hydrogen peroxide combined with a mild caustic or hydrogen chloride. Selecting a higher caustic concentration may be helpful to provide for the polished etched bottom side surface.

Both 304 and 306 provide the key feature of asymmetrically etching the bottom and top sides (i.e. first and second surfaces) of the as-cut Si wafer. The saw damaged wafer may still contain metallic contaminants and/or small cracks, no matter which sawing/cutting process is used. The slight etching of the top side provides for improving the wafer's mechanical integrity by removing these small cracks, while also removing the metallic and/or organic contaminants and preventing bowing/bending of the wafer during polish etching.

If only one surface of the as-cut Si wafer would be etched, the wafer would be subjected to mechanical stress resulting in bending/bowing, or in the worst case, wafer breakage. Bowed Si wafers are not desired in the production of solar cells for numerous reasons, including, but not limited to: uneven etching of the Si surface, mechanical problems of loading carriers/boats encountered during the subsequent passivation step, and uneven deposition of the passivation layer on the bottom side surface.

After the asymmetrical in-line etching of the as-cut Si wafers 304/306, a bottom side (i.e. the first surface, the side that was polish etched) passivation layer is applied 308. This bottom side passivation layer stack may include one or more layers of silicon oxide, silicon nitride, and/or aluminum oxide layers. The application of the passivation layer on the wafer bottom side may be done by quartz furnace processes—dry or wet, or other deposition processes such as chemical vapor deposition (CVD), plasma-enhanced CVD, atomic layer deposition (ALD) or other processes of physical depositions including sputtering, electron beam evaporating, molecular beam epitaxy, cathodic arc depositions, or the like. Other processes for applying the passivation layer may include printing, melting, sintering, dip coating, or spray coating.

After the application of the passivation layer to the wafer bottom side 308, the front side (i.e. the second surface which was only slightly etched) undergoes a front side alkaline texture etching 310. This may be done either by batch process or by inline process. The Si wafer bottom side is protected against this etching by the passivation layer. The front side alkaline texture etching may be performed with sodium hydroxide, potassium hydroxide, potassium carbonate, sodium carbonate, or any mixtures thereof, along with additional organic components e.g. isopropanol, ethylene glycols, alkoxylated glycols, certain surfactants, polysaccharides or other more. This front side texture etching may resolve any surface imperfections resulting from the slight etching of the top surface (i.e. front side) resulting from the asymmetrical etching process of 304/306.

Then, the Si wafer is doped with a dopant via dopant diffusion or implantation 312 in order to modulate electrical properties of the wafer for solar cell production. Dopants may include phosphorous or other elements of the V group of the periodic table for n doping of p-type wafer, and boron or other elements of the III group of the periodic table for p doping of n-type wafer. This step may include depositing dopant particles on the Si surface and annealing.

Following the addition of the dopant, local openings in the bottom side passivation layer stack are added 314. The bottom side local opening of the passivation layer stack may include the creating of openings in the passivation layer on the bottom side in order to subsequently create electrical contacts with the doped Si wafer through the bottom side passivation layer(s). This may be achieved via use of lasers, selective etching of the passivation layer, or the like.

In some aspects, if the PERC solar cell is manufactured without selective emitter regions, the phosphorous silicate glass (PSG) which may result from the phosphorous dopant diffusion (where phosphorous is chosen as the dopant) is removed 316. This removal may be performed by conventional PSG removal methods.

Is some aspects, if a PERC solar cell with a selective emitter is manufactured, the additional steps of the selective emitter formation and front side passivation are performed, along with PSG removal 318. The selective emitter formation may include additional doping to form the selective emitter, such as by diffusion, implantation techniques and/or laser techniques. The formed selective emitter regions may include regions on the Si wafer which are further doped for enhanced electrical connection with subsequently formed metallic contacts over at least one surface of the Si wafer. After formation of the selective emitter, the PSG is removed (similar to in 316), and a front side passivation oxidation step (e.g. to form a layer of silicon oxide) is performed.

After either 316 or 318, the final steps of PERC solar cell production are performed 320. An antireflection coating, e.g. including silicon nitride and/or silicon oxide, is applied to the front side. Then, a metallization of the front and backside (e.g. by screen printing or the like) is applied to the front and bottom sides, and the Si wafers are co-fired in order to form metallic contacts (by the aforementioned metallization). This co-firing, for example, may force the metallization through the passivation layer (e.g. formed on the front and/or bottom side, e.g. through the bottom side local openings) in order to make contact with front and/or bottom side of the doped Si wafer.

Commonly known PERC solar cells include the passivation layers in order to increase the lifetime of the generated charge carriers by reducing the recombination. Additionally, they provide the bottom side (i.e. rear side) of the solar cells with a back surface field (B SF) in proximity to the backside metallization, e.g. aluminum, where the local openings of the bottom side layer stack are formed (in 314). The patterned local BSF provides enough rear side contact without reducing the rear side passivation significantly. The process shown by flowchart 300 may correct uncompleted laser spots, i.e. interrupted openings. The increased surface roughness exhibited by the textured Si wafer structure may improve alloy formation, thereby increasing the metallization contact.

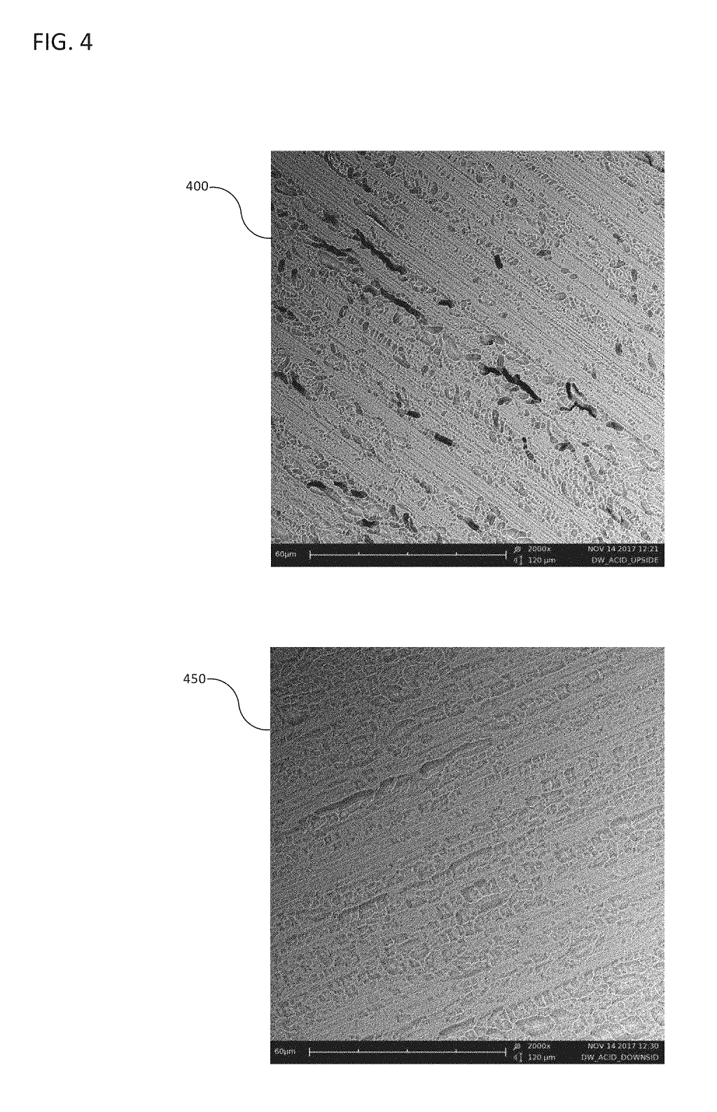

FIG. 4 shows Scanning Electron Microscope (SEM) images 400 and 450 of a top-side and a bottom side, respectively, of a diamond-wire cut Si wafer etched via an acidic asymmetrical, in-line etching process in some aspects of this disclosure.

The top-side image 400 is magnified 2000× and shows a top-side of the as-cut Si wafer which was etched less than 3 μm. As can be seen, the top side is not polish etched, but has been sufficiently etched to prevent bowing of the as-cut Si wafer, and also cracks and/fissures from the cutting of the Si wafer have been removed, thereby increasing the mechanical integrity of the Si wafer.

The bottom-side image 450 is magnified 2000× and shows a bottom-side of the as-cut Si wafer which was etched approximately 9 μm. The bottom-side, unlike the top side in 400, has been polish etched.

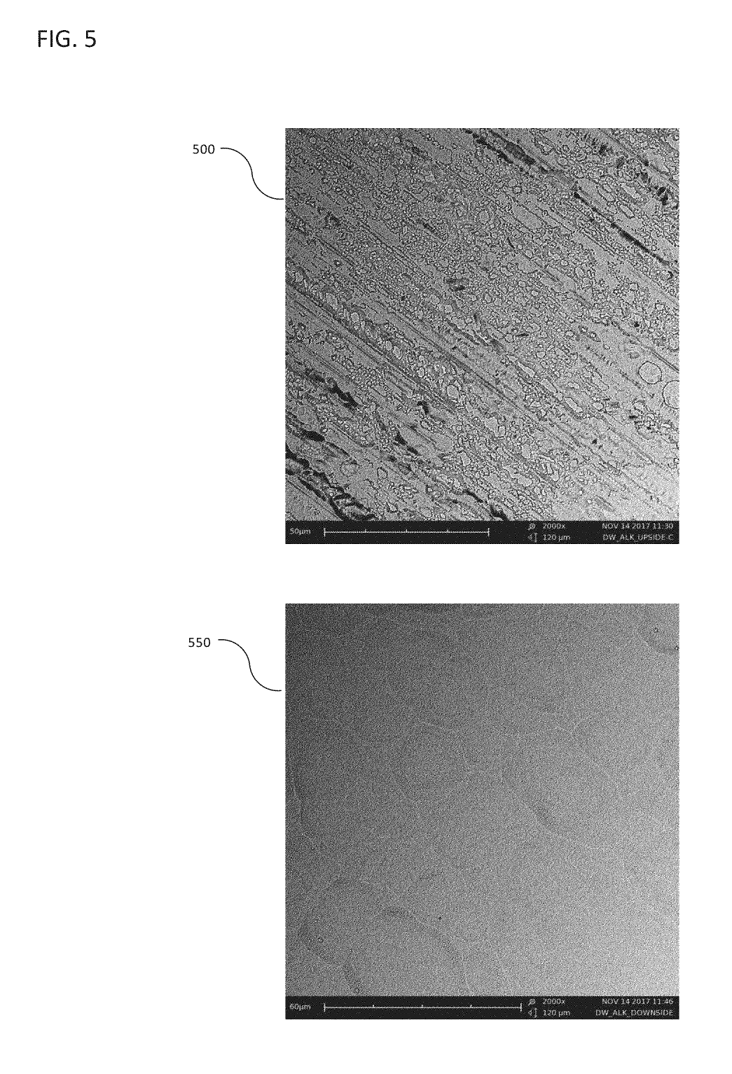

FIG. 5 shows Scanning Electron Microscope (SEM) images 500 and 550 of a top-side and a bottom side, respectively, of a diamond-wire cut Si wafer etched via an alkaline asymmetrical, in-line etching process in some aspects of this disclosure.

The top-side image 500 is magnified 2000× and shows a top-side of the as-cut Si wafer which was etched less than 3 μm. As can be seen, the top side is not polish etched, but has been sufficiently etched to prevent bowing of the as-cut Si wafer, and also cracks and/fissures from the cutting of the Si wafer have been removed, thereby increasing the mechanical integrity of the Si wafer.

The bottom-side image 550 is magnified 2000× and shows a bottom-side of the as-cut Si wafer which was etched approximately 9 μm. As can be seen from images 500 and 550, the bottom-side, unlike the top-side, of the Si wafer is polish etched.

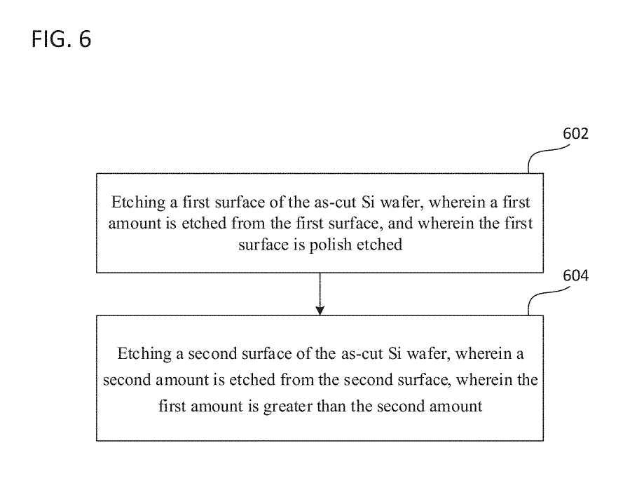

FIG. 6 shows a flowchart 600 describing a process for in-line etching of an as-cut Si wafer in some aspects. The as-cut Si wafer is saw-damaged from the Si wafer cutting process, e.g. diamond wire cutting, and has not been subjected to another etching process prior to the process shown in flowchart 600.

In 602, a first surface of the as-cut Si wafer is etched, wherein a first amount is etched from the first surface, and the first surface is polish etched. This first surface may be the bottom side of the Si wafer as shown in FIGS. 1 and 2. In total, about 7 μm to about 11 μm may etched from the first surface.

In 604, a second surface of the as-cut Si wafer is etched, wherein a second amount is etched from the second surface, wherein the first amount is greater than the second amount. The second surface may be the top side of the Si wafer as shown in FIGS. 1 and 2. In total, about 0.5 μm to about 3 μm may etched from the second surface.

The following examples pertain to further aspects of this disclosure:

In Example 1, a method for inline etching a saw damaged as-cut Si wafer, the method including etching a first surface of the as-cut Si wafer, wherein a first amount is etched from the first surface; and etching a second surface of the as-cut Si wafer, wherein a second amount is etched from the second surface, wherein the first amount is greater than the second amount, wherein the saw damaged as-cut Si wafer is not subjected to an etching prior to said inline etching.

In Example 2, the subject matter of Example 1 may include wherein the etching of the second surface is performed at least partially during the etching of the first surface.

In Example 3, the subject matter of Example 1 may include wherein the etching of the second surface is performed during the etching of the first surface.

In Example 4, the subject matter of Examples 1-3 may include wherein the first amount is about 7 μm to about 11 μm.

In Example 5, the subject matter of Examples 1-4 may include wherein the second amount is about 0.5 μm to about 3 μm.

In Example 6, the subject matter of Examples 1-5 may include wherein the as-cut Si wafer is monocrystalline or a quasi-monocrystalline.

In Example 7, the subject matter of Examples 1-6 may include further comprising applying an etchant solution to the second surface via etchant raining, dripping or spraying, and applying the etchant solution to the first surface via grooved rollers at least partially submerged in the etchant solution or via porous rollers, through which the etchant solution is provided from an etchant reservoir tank connected to the axes of the porous rollers.

In Example 8, the subject matter of Example 7 may include wherein the rollers are grooved or porous.

In Example 9, the subject matter of Examples 1-8 may include removing at least some of the etchant solution from the second surface, after which the etchant solution continues to be applied to the first surface.

In Example 10, the subject matter of Examples 1-9 may include applying a first etchant solution to the first surface and the second surface while the wafer is submerged in the first etchant solution, and subsequently applying a second etchant solution to the first surface (e.g. as shown in some aspects of FIG. 2). In a first aspect, the first etchant solution and the second etchant solution may be the same, i.e. they may have the same composition, concentration, and temperature. In a second aspect, the first etchant solution and the second etchant solution may differ in at least one a composition, a concentration, and/or a temperature. For example, if the first etchant solution and the second etchant solution are different, the second etchant solution may have a higher concentration (i.e. either higher acidity or alkalinity) and/or higher temperature than the first etchant solution.

In Example 11, the subject matter of Example 10 may include removing at least some of the first etchant solution from the second surface, after which the second etchant solution is applied to the first surface.

In Example 12, the subject matter of Examples 1-11 may include wherein the etching solution comprises an acidic etching agent.

In Example 13, the subject matter of Example 12 may include wherein the acidic etching agent is an aqueous solution comprising at least one acid selected from the group consisting of: HF, HCl, HBr, HI, AcOH, HNO₃, H₃PO₄, H₂SO₄, citric acid, oxalic acid, and lactic acid.

In Example 14, the subject matter of Examples 12-13 may include wherein the acidic etching agent comprises a heated mixture of HNO₃ and HF.

In Example 15, the subject matter of Examples 12-14 may include wherein the mixture consists of HNO₃ (about 65-70 wt % in water) and HF (about 47-60 wt % in water), wherein the volume ratio of HNO₃:HF is, prior to the etching of the first and second surfaces, in the range of about 6:1 to 10:1. In some aspects, this ratio may shift to a final ratio of about 2.5:1 to 1.2:1 after the etching of the first surface and the second surface.

In Example 16, the subject matter of Examples 12-15 may include wherein the acidic etching agent is heated between about 20° C. and about 55° C. In some aspects, the acidic etching agent is heated between about 30° C. and about 50° C. In some aspects, the acidic etching agent is heated between about 35° C. and about 50° C.

In Example 17, the subject matter of Examples 1-11 may include wherein the etching solution comprises an alkaline etching agent.

In Example 18, the subject matter of Example 17 may include wherein the alkaline etching agent is an aqueous solution of KOH or NaOH. The concentration is from about 10% up to about 50% (wt % in water). The wafer speed is significant lower for the alkaline etching compared to the one at the acidic etching. In one exemplary aspect, the alkaline etchant solution may include KOH at a concentration of about 15 wt % and a process temperature of about 80° C., where the wafer is moved at about 0.8 m/min along the rollers and the distance from the etchant rain box 120 to the top side removal element 145 in FIG. 1 is about 300 mm. In this exemplary aspect, approximately 9-10 μm may be etched off of the bottom side (i.e. first surface) and approximately 1-2 μm may be etched off of the top side (i.e. second surface).

In Example 19, the subject matter of Examples 17-18 may include wherein the alkaline etching agent is heated between about 80° C. and about 95° C.

In Example 20, a method for inline etching a saw damaged as-cut Si wafer with an acidic etchant solution, the method including etching a first surface of the as-cut Si wafer with the acidic etchant solution, wherein a first amount is etched from the first surface; and etching a second surface of the as-cut Si wafer with the acidic etchant solution, wherein a second amount is etched from the second surface, wherein the first amount is greater than the second amount, wherein the saw damaged as-cut Si wafer is not subjected to an alkaline etching prior to said inline etching.

In Example 21, the subject matter of Example 20 may include any subject matter from Examples 2-16.

In Example 22, the subject matter of Examples 1-21 may include removing at least some of the etchant solution from the first surface after the removing of at least some of the etchant from the second surface.

In Example 23, the subject matter of Examples 1-22 may include applying the etchant solution to the first surface for a greater amount of time than the second surface.

In Example 24, a method for inline etching a saw damaged as-cut Si wafer, the method including etching a first and a second surface of the as-cut Si wafer with a first etchant solution for a first amount of time, and subsequently etching the first surface for a second amount of time with a second etchant solution so that a greater amount of material is etched off the first surface than the second surface.

In Example 25, the subject matter of Example 24 may include removing or rinsing off the first etchant solution from the second surface.

In Example 26, a method for producing a solar cell including the inline etching of the as-cut Si wafer as described in any one of Examples 1-25.

While the above descriptions and connected figures may depict components as separate elements, skilled persons will appreciate the various possibilities to combine or integrate discrete elements into a single element. Conversely, skilled persons will recognize the possibility to separate a single element into two or more discrete elements, such as splitting a single element into two or more separate element, separating a chip or chassis into discrete elements originally provided thereon.

It is appreciated that implementations of methods detailed herein are exemplary in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for inline etching a saw damaged as-cut Si wafer, the method comprising:
etching a first surface of the as-cut Si wafer, wherein a first amount is etched from the first surface and the first surface is polish etched; and
etching a second surface of the as-cut Si wafer, wherein a second amount is etched from the second surface, wherein the first amount is greater than the second amount,
wherein the saw damaged as-cut Si wafer is not subjected to another etching prior to said inline etching.

2. The method of claim 1, wherein the etching of the second surface is performed during the etching of the first surface.

3. The method of claim 1, wherein the first amount is about 7 μm to about 11 μm.

4. The method of claim 4, wherein the second amount is about 0.5 μm to about 3 μm.

5. The method of claim 1, wherein the as-cut Si wafer is monocrystalline or quasi-monocrystalline.

6. The method of claim 1, further comprising applying an etchant solution to the second surface via raining, dripping or spraying, and applying the etchant solution to the first surface via grooved rollers at least partially submerged in the etchant solution or via porous rollers, through which the etchant solution is provided from an etchant reservoir tank connected to the axes of the porous rollers.

7. The method of claim 6, further comprising removing at least some of the etchant solution from the second surface, after which the etchant solution continues to be applied to the first surface.

8. The method of claim 1, further comprising applying a first etchant solution to the first and second surface while the wafer is submerged in the first etchant solution, and subsequently applying a second etchant solution to the first surface.

9. The method of claim 8, further comprising removing at least some of the first etchant solution from the second surface, after which the second etchant solution is applied to the first surface.

10. The method of claim 1, wherein the etchant solution comprises an acidic etching agent.

11. The method of claim 10, wherein the acidic etching agent is an aqueous solution comprising at least one acid selected from the group consisting of: HF, HCl, HBr, HI, AcOH, HNO₃, H₃PO₄, H₂SO₄, citric acid, oxalic acid, and lactic acid.

12. The method of claim 10, wherein the acidic etching agent comprises a heated mixture of HNO₃ and HF.

13. The method of claim 12, wherein the mixture consists of HNO₃ (about 65-70 wt % in water) and HF (about 47-50 wt % in water), wherein the volume ratio of HNO₃:HF is, prior to the etching of the first and second surfaces, in the range of about 6:1 to 10:1.

14. The method of claim 10, wherein the acidic etching agent is heated between about 20° C. and about 55° C.

15. The method of claim 1, wherein the etchant solution comprises an alkaline etching agent.

16. The method of claim 15, wherein the alkaline etching agent is an aqueous solution of KOH or NaOH.

17. The method of claim 16, wherein the concentration of the aqueous solution of KOH or NaOH is about 10 wt % to 50 wt % in water.

18. The method of claim 15, wherein the alkaline etching agent is heated between about 80° C. and about 95° C.

19. A method for inline etching a saw damaged as-cut Si wafer with acidic etchant solution, the method comprising:
etching a first surface of the as-cut Si wafer, wherein a first amount is etched from the first surface and the first surface is polish etched; and
etching a second surface of the as-cut Si wafer, wherein a second amount is etched from the second surface, wherein the first amount is greater than the second amount,
wherein the saw damaged as-cut Si wafer is not subjected to an alkaline etching prior to said inline etching.
